(19) United States
(12) Patent Application Publication
(10) Pub. No.: US 2024/0120445 A1
(43) Pub. Date: Apr. 11, 2024

(54) OPTOELECTRONIC SEMICONDUCTOR CHIP AND METHOD OF OPERATING OPTOELECTRONIC SEMICONDUCTOR CHIP

(71) Applicant: AMS-OSRAM INTERNATIONAL GMBH, Regensburg (DE)

(72) Inventors: Korbinian PERZLMAIER, Regensburg (DE); Alexander F. PFEUFFER, Regensburg (DE)

(21) Appl. No.: 18/546,362

(22) PCT Filed: Feb. 10, 2022
(86) PCT No.: PCT/EP2022/053212

§ 371 Date: Aug. 14, 2023

(30) Foreign Application Priority Data
Feb. 19, 2021 (DE) 10 2021 103 984.3

(51) Int. Cl. H01L 33/24; H01L 27/15; H01L 33/62

(52) U.S. Cl. CPC H01L 33/24; H01L 27/15; H01L 33/62

(57) ABSTRACT

In at least one embodiment an optoelectronic semiconductor chip includes an emission side, an assembly side opposite the emission side, and a semiconductor body. The semiconductor body includes a first semiconductor layer, a second semiconductor layer, and an active zone between the first semiconductor layer and the second semiconductor layer. The semiconductor body further has at least two emission regions arranged next to each other as in view of the emission side. A first emission region includes a first portion of the active zone and a second emission region including a second portion of the active zone. The emission regions are monolithically integrated in the semiconductor body. In a cross-section along a main extension plane of the active zone, the first portion of the active zone has an area at least twice as large as the second portion of the active zone.

### CROSS-REFERENCE TO RELATED APPLICATIONS

This patent application is a national phase filing under section 371 of PCT/EP2022/053212, filed Feb. 10, 2022, which claims the priority of German patent application 102021103984.3, filed Feb. 19, 2021, each of which is incorporated herein by reference in its entirety.

### TECHNICAL FIELD

An optoelectronic semiconductor chip is specified. In addition, a method of operating an optoelectronic semiconductor chip is specified.

### SUMMARY

Embodiments provide an efficient optoelectronic semiconductor chip and a method for operating such a semiconductor chip.

According to at least one embodiment of the optoelectronic semiconductor chip, the optoelectronic semiconductor chip comprises an emission side and an assembly side opposite to the emission side. The semiconductor chip further comprises a semiconductor body with a first semiconductor layer, a second semiconductor layer, and an active zone arranged between the first semiconductor layer and the second semiconductor layer. For example, the first semiconductor layer is arranged between the active zone and the emission side.

For example, the first semiconductor layer comprises at least one n-type layer. For example, the second semiconductor layer comprises at least one p-type layer. Alternatively, the first semiconductor layer comprises at least one p-type layer and the second semiconductor layer comprises at least one n-type layer.

In particular, the active zone includes at least one quantum well structure in the form of a single quantum well, SQW for short, or in the form of a multi-quantum well, MQW for short, for generating electromagnetic radiation. Additionally, the active zone includes one, preferably multiple, secondary well structures. For example, radiation in the blue or green or red spectral range or in the UV range or in the IR range is generated in the active zone during intended operation. In particular, it is possible that electromagnetic radiation in a wavelength range between including the IR range and including the UV range is generated in the active zone.

For example, the semiconductor layer sequence is based on a III-V compound semiconductor material, for example, a nitride compound semiconductor material, such as AlₙIn₁₋ₙ₋ₘGaₘN, or a phosphide compound semiconductor material, such as AlₙIn₁₋ₙ₋ₘGaₘP, or an arsenide compound semiconductor material, such as AlₙIn₁₋ₙ₋ₘGaₘAs, where 0≤n≤1, 0≤m≤1, and m+n≤1, respectively. Thereby, the semiconductor layer sequence may comprise dopants as well as additional components. For the sake of simplicity, however, only the essential constituents of the crystal lattice of the semiconductor layer sequence are given, even though these may in some cases be replaced and/or supplemented by small amounts of additional substances.

During operation, electromagnetic radiation generated in the active zone is emitted in particular via the emission side of the semiconductor chip. Via the assembly side the semiconductor chip can be mounted on an external carrier, for example a printed circuit board. Preferably, no radiation is emitted via the assembly side during intended operation.

According to at least one embodiment of the optoelectronic semiconductor chip or its embodiment described above, the semiconductor body comprises at least two emission regions arranged next to each other in view of the emission side. A first emission region comprises a first portion of the active zone and a second emission region comprises a second portion of the active zone. In a cross-section along a main extension plane of the active zone, the first portion of the active zone has an area at least twice as large as the second portion of the active zone. In particular, the first portion has an area in this cross-section at least 5 times as large or at least 10 times as large or at least 20 times as large as the second portion of the active zone.

The two emission regions are monolithically integrated in the semiconductor body. The emission regions are manufactured, for example, by means of a common growth process. The emission regions comprise, for example, at least one semiconductor layer extending over all emission regions.

The emission regions are specified in particular by their proportions of the active zone. For example, the first portion is separated from the second portion. In particular, the emission regions can be operated independently of each other.

In at least one embodiment of the optoelectronic semiconductor chip, the optoelectronic semiconductor chip comprises an emission side, an assembly side opposite the emission side, and a semiconductor body. The semiconductor body comprises a first semiconductor layer, a second semiconductor layer, and an active zone between the first semiconductor layer and the second semiconductor layer. The semiconductor body further comprises at least two emission regions arranged next to each other in view of the emission side. A first emission region of the at least two emission regions comprises a first portion of the active zone, and a second emission region of the at least two emission regions comprises a second portion of the active zone. The emission regions are monolithically integrated in the semiconductor body. In a cross-section along a main extension plane of the active zone, the first portion of the active zone has an area at least twice as large as the second portion of the active zone. Optionally, the emission regions are electrically separated from each other by a separation zone of the semiconductor body and/or an electrical conductivity of the second semiconductor layer in the separation zone is at least a factor of 10 lower than in the remaining second semiconductor layer.

An optoelectronic semiconductor chip described here is based, inter alia, on the following technical characteristics. For semiconductor chips used in display applications, dimmability over a wide brightness range is often required. This is particularly necessary to achieve a suitable color temperature, color location and/or brightness. Appropriate dimming can be achieved, for example, by adjusting the operating current or by pulse width modulation. In practice, this requires electrical dimming over several orders of magnitude, for example dimming by a factor of moo or more. At the same time, semiconductor chips have a relatively narrow optimum range of their performance with respect to the operating current. In the optimum range, for example, a quantum yield or efficiency of the semiconductor chip exhibits a local or global maximum. A high or low brightness conventionally leads to a leaving of this optimum range, whereby the efficiency of the semiconductor chip decreases. In addition, leaving the optimum range causes increased heat generation.

The semiconductor chip described here makes use, inter alia, of the idea of defining a plurality of emission regions in a semiconductor chip whose optimum ranges are different. That is, each emission region has its optimum range at a specific operating current. These operating currents differ from emission region to emission region. For this purpose, the emission regions each have a portion of the active zone, whereby the size of the portions differs.

In operation, for example, different emission regions are individually or in combination supplied with current. Advantageously, this allows the semiconductor chip to be dimmed. The emission regions can each be operated in the optimum range or relatively close to the optimum range, allowing the semiconductor chip to be operated efficiently. If such semiconductor chips are used in a display, a color fastness and/or a brightness of an image to be shown on the display can be adjusted particularly well.

For example, a display is equipped with semiconductor chips described here, in each of which several emission regions are monolithically integrated. This has the advantage, for example, that a large number of individual semiconductor chips, each of which has only a single emission region, do not have to be transferred and combined. The effort required to assemble the display is reduced and the display can be manufactured more easily and at lower cost.

According to at least one embodiment of the optoelectronic semiconductor chip or one of its embodiments described above, the first emission region has a first maximum luminous flux. The second emission region has a second maximum luminous flux. The first luminous flux and the second luminous flux are different from each other.

For example, the first emission region has the first maximum luminous flux at a first operating current. For example, the second emission region has the second maximum luminous flux at a second operating current. For example, the first operating current and the second operating current differ. For example, the first operating current and the second operating current differ by at least a factor of 1.5 or at least a factor of 2 or at least a factor of 3.

For example, at the first operating current, the first emission range has an optimum range with respect to its power. At the second operating current, the second emission range has, for example, an optimum range.

According to at least one embodiment of the optoelectronic semiconductor chip or its embodiment just described, the first maximum luminous flux is greater than the second maximum luminous flux by at least a factor of 2. In particular, the first maximum luminous flux is greater than the second maximum luminous flux by at least a factor of 10 or at least a factor of 100. With different maximum luminous fluxes, the semiconductor chip can advantageously be dimmed over several orders of magnitude during operation.

According to at least one embodiment of the optoelectronic semiconductor chip or one of its embodiments described above, the second emission region comprises a mesa structure. Mesa edges of the mesa structure completely penetrate the second semiconductor layer and the active zone of the semiconductor body starting from the assembly side. The second portion of the active zone is bounded by the mesa edges. In particular, the mesa structure separates the first portion of the active zone from the second portion of the active zone. During the manufacture of the semiconductor chip, the mesa edges are formed in particular by etching. In this case in particular, the mesa edges have etch marks.

Alternatively, it is possible that the mesa structure is produced in a growth process. In this process, for example, the first semiconductor layer of the first emission region and the first portion of the active zone are grown separately from the first semiconductor layer of the second emission region and the second portion of the active zone. Then, in particular, the second semiconductor layer is grown as a common semiconductor layer on the first portion of the active zone and the second portion of the active zone.

According to at least one embodiment of the optoelectronic semiconductor chip or its embodiments described above, the mesa structure is formed in a central region of the semiconductor body in view of the assembly side. In particular, each mesa edge of the mesa structure is spaced apart from side surfaces of the semiconductor body. Side surfaces of the semiconductor body extend transversely to the assembly side. The side surfaces connect in particular a surface of the semiconductor body facing the assembly side with a surface of the semiconductor body facing the emission side.

In this embodiment, the first emission region forms a closed frame around the second emission region in view of the emission side. Advantageously, by arranging the mesa structure in a central region of the semiconductor body, a radiation characteristic of the semiconductor chip can be achieved which is independent of the current supply of the emission regions. By this is meant that the radiation characteristic in operation of the semiconductor chip is essentially identical in the case that the first emission region is supplied with current and in the case that the second emission region is supplied with current.

According to at least one embodiment of the optoelectronic semiconductor chip or one of its embodiments described above, the emission regions are electrically separated from each other by a separation zone of the semiconductor body. For example, one or more layers of the semiconductor body in the separation zone has a lower electrical conductivity than outside the separation zone. In particular, the second semiconductor layer has a lower electrical conductivity in the separation zone than outside the separation zone. The electrical conductivity is lowered in the separation zone, for example, in such a way that electrical separation of the emission regions is achieved. In the region of the separation zone, preferably no radiation is generated in the active zone.

If the semiconductor body, in particular the second emission region, comprises a mesa structure, for example, the separation zone is preferably arranged in the region of the mesa edges. Advantageously, a distance of the emission regions in lateral direction can be increased by arranging the separation zone. In other words, the emission regions can be further restricted in the lateral direction by the separation zone. By “lateral direction” is meant here and in the following a direction that is parallel to the main extension plane of the active zone.

According to at least one embodiment of the optoelectronic semiconductor chip or one of its embodiments described above, the first semiconductor layer, the second semiconductor layer and the active zone are each formed as continuous layers. The emission regions are electrically separated from each other, for example, by the separation zone of the semiconductor body. The separation zone is preferably arranged between the emission regions. The separation zone is, for example, simply continuous. Alternatively, the separation zone is formed to be multi-contiguous, in particular in the case where more than two emission regions are present. The electrical conductivity is reduced in the separation zone, for example, in such a way that electrical separation of the emission regions is achieved.

According to at least one embodiment of the semiconductor chip having a separation zone, an electrical conductivity of the second semiconductor layer in the separation zone is lower by at least a factor of 10 or at least a factor of 100 or at least a factor of woo than in the remaining second semiconductor layer.

According to at least one embodiment of the optoelectronic semiconductor chip having a separation zone, the second semiconductor layer in the separation zone has a defect density that is at least a factor of 2 or at least a factor of 10 or at least a factor of 100 or at least a factor of moo greater than a defect density outside the separation zone. For example, impurity atoms are introduced into the second semiconductor layer in the separation zone. The impurity atoms are, for example, hydrogen atoms or argon atoms. The concentration of the impurity atoms is, for example, at least 1×10¹⁷ cm-3. The impurity atoms have been introduced into the second semiconductor layer, for example, by means of ion implantation. Alternatively or additionally, the second semiconductor layer in the separation zone has been processed with a plasma, for example a hydrogen plasma, to increase the defect density in the separation zone.

According to at least one embodiment of the optoelectronic semiconductor chip with a separation zone, dopants are inactivated in the separation zone. The inactivation of the dopants causes, for example, a reduction of the electrical conductivity. For example, the dopants in the second semiconductor layer are inactivated in the separation zone. The dopants are inactivated, for example, by an incorporation of hydrogen atoms in the separation zone. The hydrogen atoms are introduced into the separation zone by means of ion implantation or by means of a plasma, for example. If the electrical conductivity in the separation zone is reduced due to inactivation of the dopants, it is possible that the defect density in the separation zone is the same or substantially the same compared to the remaining semiconductor layer sequence.

According to at least one embodiment, the separation zone is formed in a continuous semiconductor layer. Alternatively or additionally, the separation zone can be formed as a recess of the semiconductor body.

According to at least one embodiment of the optoelectronic semiconductor chip or one of its embodiments described above, the first semiconductor layer is arranged between the active zone and the emission side and the semiconductor body has at least one recess. The recess extends from the assembly side into the first semiconductor layer. A first contact structure is arranged at least partially in the recess. The first semiconductor layer is electrically conductively connected to the first contact structure. Preferably, the first electrical contact structure is electrically isolated from the second semiconductor layer and the active zone.

In one embodiment, the first contact structure comprises, for example, one or more metals. The metals are, for example, gold, silver, nickel, titanium, platinum, rhodium, and/or aluminum.

In one embodiment, the first contact structure additionally or alternatively comprises, for example, a transparent, electrically conductive oxide, or TCO for short, such as indium tin oxide, or ITO for short, or zinc oxide, or ZnO for short.

The first contact structure has in particular a first electrical connection surface, with the first electrical connection surface being arranged on the assembly side. The first contact structure thus preferably extends from the assembly side in the recess to the first semiconductor layer. Via the first connection surface, the first semiconductor layer is externally contacted and supplied with current during intended operation. The first contact structure is preferably formed with a metal in the region of the first connection surface.

According to at least one embodiment of the optoelectronic semiconductor chip or one of its embodiments described above, the second semiconductor layer is electrically conductively connected to a second contact structure. For example, the second semiconductor layer is supplied with current by the second contact structure during intended operation.

In one embodiment, the second contact structure comprises, for example, one or more metals. The metals are, for example, gold, silver, nickel, titanium, platinum, rhodium, and/or aluminum.

In one embodiment, the second contact structure additionally or alternatively comprises, for example, a transparent, electrically conductive oxide, abbreviated as TCO, such as indium tin oxide, abbreviated as ITO, or zinc oxide, abbreviated as ZnO.

In particular, the second contact structure comprises at least two second electronic connection surfaces, with at least one of the second electrical connection surfaces being assigned to each emission region. The second electrical connection surfaces of the second contact structure are arranged on the assembly side of the semiconductor chip. Via the second electrical connection surfaces, the second semiconductor layer is electrically contacted and supplied with current during operation of the semiconductor chip. The second contact structure is preferably formed with a metal in the region of the second connection surfaces.

For example, exactly one second electrical connection surface is assigned to each emission region. Alternatively or additionally, exactly one emission region is assigned to each second electrical connection surface. In particular, the assignment between the emission regions and the second electrical connection surfaces is unambiguous.

According to at least one embodiment of the semiconductor chip or one of its embodiments described above, all second electrical connection surfaces are of equal size in a projection onto the assembly side. By “of equal size” is meant here and in the following that in projection onto the assembly side and/or in view of the assembly side the area of any two second electrical connection surfaces differs by a factor of at most 1.1 or 1.2 or 1.4.

For example, the second connection surfaces have the same geometric shape in this projection. For example, the second connection surfaces are the same size as seen from the assembly side and/or have the same geometric shape. Advantageously, this makes electrical contacting and/or mechanical assembly of the semiconductor chip, for example with a solder connection, relatively simple. In addition, the optoelectronic semiconductor chip can be cooled by the electrical connection surfaces during intended operation.

For example, in viewed of the assembly side, the assembly side is at least 50% covered by the second electrical connection surfaces.

In the case that the optoelectronic semiconductor chip has first and second connection surfaces, all first and second connection surfaces are preferably the same size in a projection onto the assembly side. For example, in view of the assembly side, the assembly side is then covered by at least 70% or at least 80% of the electrical connection surfaces.

According to at least one embodiment of the optoelectronic semiconductor chip or one of its embodiments described above, a side of the second semiconductor layer facing away from the emission side and side surfaces of the semiconductor body extending transversely thereto are covered at least in places by a passivation layer. The passivation layer is preferably formed with an electrically insulating material such as silicon oxide or silicon nitride. For example, the passivation layer is partially or completely formed as a dielectric mirror. The passivation layer preferably comprises a Bragg reflector in which low refractive dielectric layers alternate with high refractive dielectric layers. The passivation layer preferably comprises a dielectric mirror in the region of the assembly side.

In the case that the semiconductor chip comprises a first and/or second contact structure, the passivation layer in particular has breakthroughs in which the first and/or second contact structure are/is arranged.

According to at least one embodiment of the optoelectronic semiconductor chip or one of its embodiments described above, the semiconductor chip comprises a simply connected emission surface through which all emission regions emit during operation. For example, the emission surface is formed by a surface of the first semiconductor layer facing away from the active zone.

According to at least one embodiment of the optoelectronic semiconductor chip or one of its embodiments described above, the semiconductor chip is a micro-LED. For example, the micro-LED has an emission surface smaller than 0.003 mm². Alternatively or additionally, an edge length of the emission surface is, for example, at most 100 μm or at most 50 μm or at most 10 μm. Semiconductor chips with such a small emission region are particularly suitable for use in a high-resolution display.

According to at least one embodiment of the optoelectronic semiconductor chip or one of its embodiments described above, all emission regions are configured to emit radiation of the same wavelength range. In particular, all emission regions are based on the same semiconductor material. For example, each semiconductor chip forms a pixel of a display, in particular a monochromatic display.

If the display is a color display, each pixel is preferably formed by at least three subpixels. In particular, each subpixel is formed by a semiconductor chip described herein, preferably implemented as a micro-LED. For example, a first subpixel is configured to emit radiation of a red wavelength range. A second subpixel is configured, for example, to emit radiation of a green wavelength range. A third subpixel is configured, for example, to emit radiation of a blue wavelength range. A pixel constructed in this way is also referred to as an RGB pixel.

According to at least one embodiment of the optoelectronic semiconductor chip or one of its embodiments described above, the semiconductor chip comprises three or more emission regions.

For example, during operation, a third emission region is supplied with current together with the second emission region. For example, the same operating current is then applied to the second and third emission regions.

For example, the third emission region and the second emission region are assigned a common second connection surface.

Alternatively, a second connection surface is uniquely assigned to both the second emission region and the third emission region. In this case, an identical operating current is applied to these two connection surfaces during operation, for example. It is also possible that the operating current of the second emission region and the operating current of the third emission region are different from each other.

According to at least one embodiment, the second emission region comprises a mesa structure. Mesa edges of the mesa structure partially or, preferably, completely penetrate the second semiconductor layer and the active zone (5) of the semiconductor body, starting from the assembly side. The mesa edges may terminate in the first semiconductor layer. Furthermore, it is possible that the second portion of the active zone is bounded by the mesa edges.

A method of operating an optoelectronic semiconductor chip is further specified. The optoelectronic semiconductor chip described herein and its embodiments can be operated in particular by the method. That is, all features disclosed for the semiconductor chip are also disclosed for the method, and vice versa.

In at least one embodiment of the method, a target luminous flux for the semiconductor chip is predetermined. For example, the semiconductor chip is used in a display. In this case, the target luminous flux results in particular from a brightness of an image to be displayed on the display or from a brightness and/or a color location of an image section.

In a further step of the method, the emission regions required to generate the predetermined target luminous flux are determined. For example, the determination of the target luminous flux shows that the target luminous flux is achieved by the first luminous flux of the first emission region or by the second luminous flux of the second emission region. It is also possible that the target luminous flux is achieved by the sum of the luminous fluxes of the first and second emission regions.

Subsequently, the first emission region, the second emission region or the first and the second emission region are supplied with current so that the semiconductor chip as a whole emits the specified target luminous flux. The emission regions are operated, for example, by means of pulse width modulation. Pulse-width modulation is also known PWM for short. Alternatively or additionally, the emission regions are each operated with a continuous operating current.

The emission regions can also be controlled differently, for example. This means, for example, that the first emission region is operated with a continuous operating current and the second emission region by means of pulse-width modulation.

For example, if a plurality of the semiconductor chips is used in a display, in particular a color display, an average brightness of the display is set via a continuous operating current. Deviations of the brightness of individual pixels or subpixels from the average brightness are then achieved, for example, by operating the emission regions using pulse-width modulation. In particular, the continuous operating current is modulated. Such deviations in brightness are predetermined based on, for example, the brightness of individual pixels of the image to be displayed or the color locations of the pixels of the image to be displayed.

For example, the current is applied at the first/second operating current at which the first/second emission region has its maximum luminous flux.

Alternatively, it is possible that the first/second emission region is operated with an operating current that is different from said first/second operating current. In this case, each emission region does not emit its maximum luminous flux, but a lower luminous flux.

The total luminous flux of the semiconductor chip is then derived from the luminous fluxes of the controlled emission regions. By selectively current supply the emission regions individually or in groups or all emission regions, the total luminous flux of the semiconductor chip can thus be adapted to the target luminous flux.

It is also possible for the semiconductor chip to comprise more than two emission regions. In this case, for example, one, two or three or more emission regions are operated individually or in groups according to the determined target luminous flux in order to achieve the target luminous flux. In particular, the statements made for the operation of the first and second emission regions, for example with respect to the operating current, also apply to the further emission regions.

According to at least one embodiment of the method, the first emission region is operated with an operating current that differs from an operating current of the second emission region. For example, the operating currents differ by at least a factor of 1.5 or at least a factor of 2 or at least a factor of 3.

Further advantages and advantageous embodiments and further developments of the semiconductor chip and the method result from the following exemplary embodiments shown in connection with in schematic drawings. Identical, similar and similarly acting elements are provided with the same reference signs in the figures. The figures and the proportions of the elements shown in the figures with respect to one another are not to be regarded as true to scale. Rather, individual elements may be shown exaggeratedly large for better representability and/or for improved comprehensibility.

### BRIEF DESCRIPTION OF THE DRAWINGS

In the figures:

FIGS. 1-4 and 7 show exemplary embodiments of a semiconductor chip described herein in various views; and

FIGS. 5 and 6 show exemplary embodiments of semiconductor bodies for semiconductor chips described herein in sectional views.

### DETAILED DESCRIPTION OF ILLUSTRATIVE EMBODIMENTS

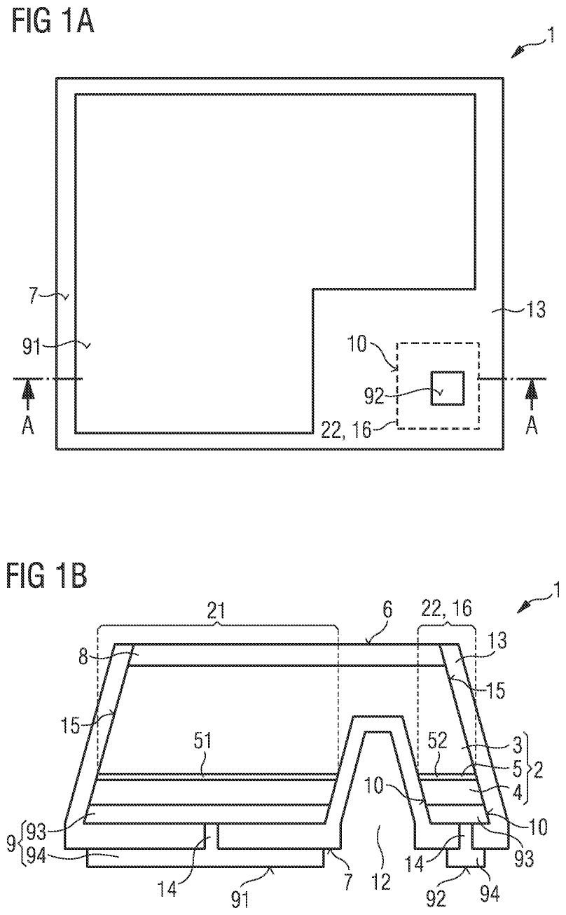

FIGS. 1A and 1B illustrate an optoelectronic semiconductor chip 1 according to a first exemplary embodiment. FIG. 1A shows a view of an assembly side 7 of the semiconductor chip 1, and FIG. 1B shows a section through the drawing plane of FIG. 1A along the line A-A drawn in FIG. 1A.

The semiconductor chip 1 comprises a semiconductor body 2. The semiconductor body 2 comprises a first semiconductor layer 3, a second semiconductor layer 4, and an active zone 5 in which electromagnetic radiation is generated during intended operation of the semiconductor chip 1. The semiconductor body 2 is based on a III-V semiconductor material, such as GaN or GaP. The first semiconductor layer 3 is, for example, an n-type GaN- or GaP-based layer or layer sequence. The second semiconductor layer 4 is, for example, a p-type GaN- or GaP-based layer or layer sequence. The active zone 5 is, for example, a GaN- or GaP-based SQW or MQW structure.

The semiconductor body 2 comprises a first emission region 21 and a second emission region 22. The emission regions 21, 22 are monolithically integrated with the semiconductor body 2. The first emission region 21 comprises a first portion 51 of the active zone 5. The second emission region 22 comprises a second portion 52 of the active zone 5. In a cross-section along a main extension plane of the active zone 5, the first portion 51 of the active zone 5 has an area at least twice as large as the second portion 52 of the active zone 5.

Due to these different areas of the portions 51, 52, the first emission region 21 has a first maximum luminous flux that differs from a second maximum luminous flux of the second emission region 22. For example, the luminous fluxes differ from each other by at least a factor of 2. In particular, the first/second maximum luminous flux is achieved when the first/second emission region 21/22 is operated with a first/second operating current. For example, the first and second operating currents differ from each other by at least a factor of 2.

The second emission region 22 comprises a mesa structure 16. Mesa edges 10 of the mesa structure 16 completely penetrate the second semiconductor layer 4 as well as the active zone 5 starting from the assembly side 7. Due to the mesa structure 16, a recess 12 is formed in the semiconductor body 2. The recess 12 separates the first section 51 from the second section 52 of the active zone 5.

On an emission side 6 opposite to the assembly side 7, the optoelectronic semiconductor chip 1 has a continuous emission surface. In particular, the emission surface is formed in a simple connected manner. In intended operation, all emission regions 21, 22 emit radiation generated in the active zone 5 through the emission surface.

A first contact structure 8 is arranged on a side of the first semiconductor layer 3 facing away from the active zone 5. The first contact structure 8 is electrically conductively connected to the first semiconductor layer 3 and is arranged for supplying the first semiconductor layer 3 with current. The first contact structure 8 preferably comprises a transparent conductive oxide such as ITO.

A second contact structure 9 is arranged on a side of the second semiconductor layer 4 facing away from the active zone 5. The second contact structure 9 is electrically conductively connected to the second semiconductor layer 4 and serves to supply the second semiconductor layer 4 with current in intended operation.

The second contact structure 9 comprises a first region 93 and a second region 94. The first region 93 makes electrical contact with the second semiconductor layer 4 and, in particular, is in direct contact with the semiconductor body 2.

The first region 93 of the second contact structure 9 comprises, for example, a transparent conductive oxide, such as ITO, and/or a metallic mirror. The metallic mirror comprises, for example, gold or silver.

The second contact structure 9 comprises electrical connection surfaces 91, 92 on its side facing away from the semiconductor body 2. The second electrical connection surfaces 91, 92 are formed in particular with the second region 94 of the second contact structure 9. The second region 94 of the second contact structure 9 comprises, for example, one or more metals, in particular copper, nickel, silver and/or gold.

The second electrical connection surfaces 91, 92 are each assigned to an emission region 21, 22. In particular, the second connection surface 91 of the first emission region 21 is electrically separated and spaced from the second connection surface 92 of the second emission region 22.

The assembly side 7 as well as side surfaces 15 of the semiconductor body 2 are covered with a passivation layer 13. The passivation layer 13 preferably comprises an electrically insulating material such as silicon dioxide or silicon nitride. The passivation layer 13 is, for example, partially or completely formed as a dielectric mirror.

The passivation layer 13 comprises breakthroughs 14 on the assembly side 7. The second contact structure 9 is arranged in the breakthroughs 14.

In view of the assembly side 7 (see FIG. 1A), it can be seen that the second electrical connection surface 92 of the second emission region 22 is limited to the mesa structure 16. In view of the assembly side 7, the second connection surface 91 of the first emission region 21 has a surface region that is many times larger than the second connection surface 92 of the first emission region 22.

The semiconductor chip 1 can be mounted on an external carrier via the assembly side 7, for example. Via the carrier, the semiconductor chip 1 is controlled and supplied with current during operation. A plurality of semiconductor chips 1 are placed on the carrier, for example, to form a display. A single semiconductor chip 1 forms, for example, a pixel or a subpixel of the display.

In operation, for example, a target luminous flux is predetermined for the semiconductor chip 1. The predetermination is made, for example, on the basis of an image to be displayed or an image section to be displayed. Depending on the target luminous flux, the emission regions 21, 22 are supplied with current individually or jointly so that a total luminous flux of the semiconductor chip 1 matches the target luminous flux as closely as possible.

In contrast to the sectional view of FIG. 1B, it is also possible for the emission side 6 to be larger than the assembly side 7. In this case, in contrast to FIG. 1B, side surfaces 15 are inclined outwards from the assembly side 7, for example. The emission side 6 is then larger than the assembly side 7, for example. Such a design is possible in all exemplary embodiments.

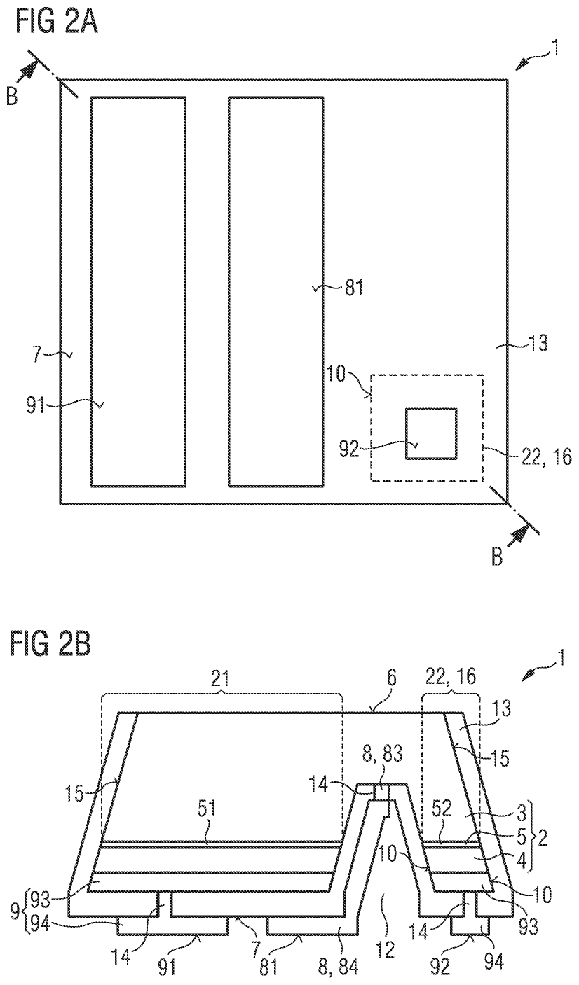

FIG. 2 illustrates an optoelectronic semiconductor chip 1 according to a second exemplary embodiment. FIG. 2A shows a view of an assembly side 7 and FIG. 2B shows a sectional view through the assembly side 7 along the line B-B shown in FIG. 2A.

The optoelectronic semiconductor chip 1 of FIG. 2 shows essentially the same features as the optoelectronic semiconductor chip 1 of FIG. 1 with the difference that the first contact structure 8 is arranged at least partially in the recess 12. In the recess 12, the passivation layer 13 has a breakthrough 14 in which a first region 83 of the first contact structure 8 is arranged.

A second region 84 of the first contact structure 8 connects the first region 83 to a first electrical connection surface 81. The first electrical connection surface 81 is arranged on the assembly side 7. The first electrical connection surface 81 and the second electrical connection surface 91 of the first emission region 21 are the same size in view of the assembly side 7 and have the same geometric shape (see FIG. 2A).

For example, the first/second region 83/84 of the first contact structure 8 comprises the same materials as the first/second region 93/94 of the second contact structure 9.

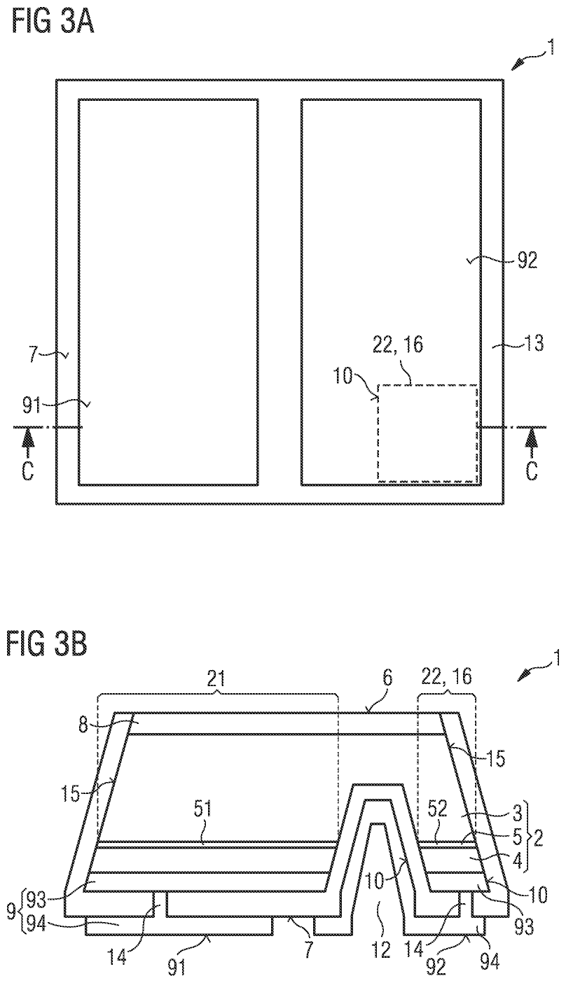

FIG. 3 illustrates an optoelectronic semiconductor chip 1 according to a third exemplary embodiment as in view of the assembly side 7 (FIG. 3A) and in a sectional view through the assembly side 7 along the line C-C (FIG. 3B).

The semiconductor chip 1 of FIG. 3 comprises substantially the same features as the semiconductor chip 1 of FIG. 1 except that the second electrical connection surface 92 of the second emission region 22 is approximately the same size and geometric shape as the second connection surface 91 of the first emission region 21 when in view of the assembly side 7. Preferably, all of the second connection surfaces 91, 92 have the same area in view of the assembly side.

Accordingly, in the sectional view of FIG. 3B, it can be seen that the second region 94 of the second contact structure 9 extends and across the recess 12. The second region 94 is at least partially disposed within the recess.

Alternatively to the representation of FIG. 3B, it is also possible that the second region 94 of the second contact structure 9 completely fills the recess 12. In this case, the recess 12 is completely filled with the material of the second region 94. Advantageously, this makes it particularly easy to make electrical contact with the connection surface 92.

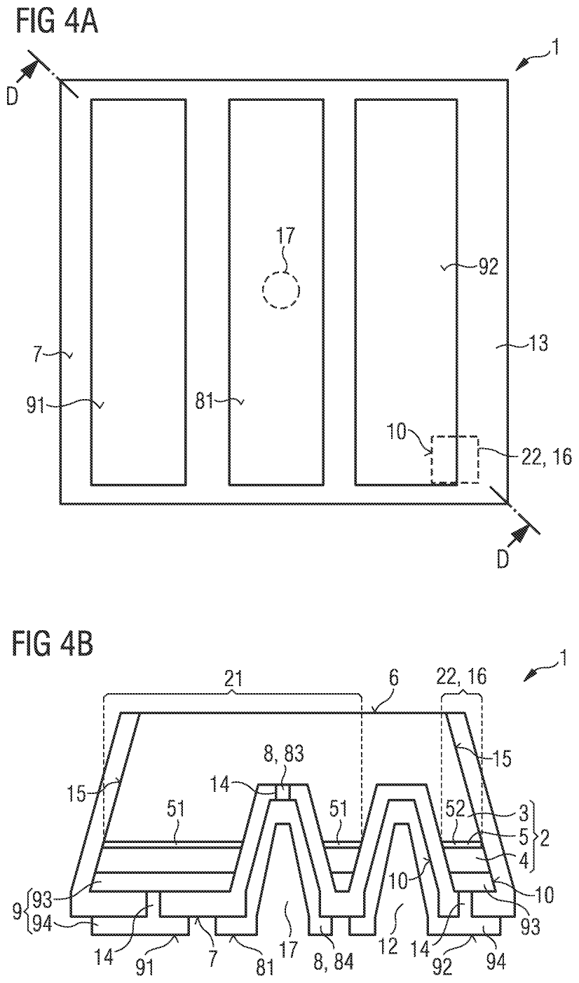

In FIG. 4, an optoelectronic semiconductor chip 1 according to a further exemplary embodiment is illustrated in view of the assembly side 7 (FIG. 4A) and sectional view along the line D-D of FIG. 4A (FIG. 4B).

In contrast to the semiconductor chip 1 of FIG. 3, the semiconductor chip of FIG. 4 has a further recess 17 in the central region of the semiconductor chip 1. The further recess 17 in the central region extends from the assembly side 7 into the first semiconductor layer 3 and completely penetrates the second semiconductor layer 4 and the active zone 5 (see FIG. 4B). The further recess 17 forms in particular a hole in the second semiconductor layer 4 and the active zone 5. The passivation layer 13 comprises a breakthrough 14 in the further recess 17, in which the first contact structure 8 is arranged analogously to FIG. 2. The first contact structure 8 extends from a first electrical connection surface 81 into the through-contact 12.

In view of the assembly side 7, the first connection surface 81 and the second connection surfaces 91, 92 are substantially the same size and have the same geometric shape (see FIG. 4A).

FIG. 5 illustrates a semiconductor body 2 for an optoelectronic semiconductor chip 1 according to a further embodiment example. In contrast to the semiconductor bodies 2 of the previously described exemplary embodiments, a second emission region 22 does not comprise a mesa structure. Rather, a second portion 52 of an active zone 5 is separated from a first portion 51 by a separation zone 11. The separation zone 11 provides an electrical separation of the second emission region 22 from a first emission region 21. In the separation zone 11, an electrical conductivity of the second semiconductor layer 4 is preferably lower by a factor of 10 or by a factor of 100 compared to the remaining second semiconductor layer 4. Thus, the second semiconductor layer 4 in the first emission region 21 is electrically separated from the second semiconductor layer 4 in the second emission region 22. Thus, the emission regions 21, 22 can be operated independently of each other.

In the separation zone 11, for example, impurity atoms, for example hydrogen atoms or argon atoms, are introduced into the semiconductor body 2, in particular into the second semiconductor layer 4. The impurity atoms cause, for example, an increase in the defect density of the second semiconductor layer 4 by at least a factor of 2, compared with the second semiconductor layer 4 outside the separation zone.

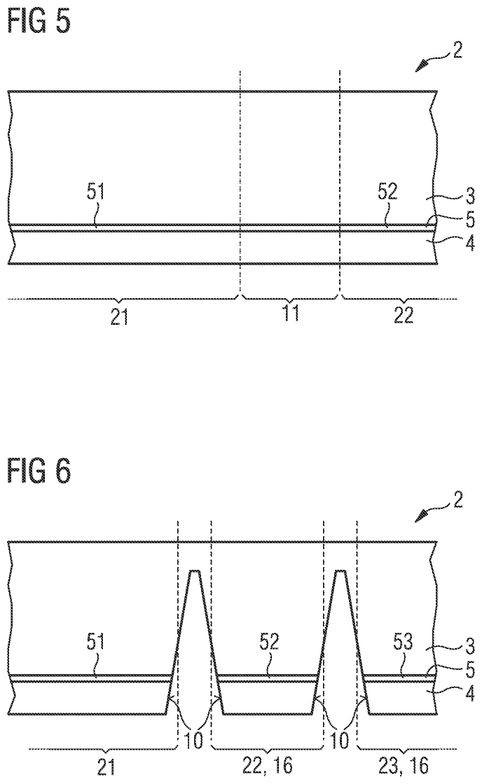

FIG. 6 illustrates a semiconductor body 2 of a semiconductor chip 1 according to a further exemplary embodiment. In contrast to the previously described exemplary embodiments, the semiconductor body 2 of FIG. 6 comprises three emission regions 21, 22, 23. The first emission region 21 is assigned to a first portion 51, the second emission region 22 is assigned to a second portion 52, and the third emission region 23 is assigned to a third portion 53 of the active zone 5. The second emission region 22 and the third emission region 23 each comprise a mesa structure 16. Mesa edges 10 of the mesa structures 16, starting from a side of the second semiconductor layer 4 facing away from the active layer 5, completely penetrate the second semiconductor layer 4 and the active zone 5.

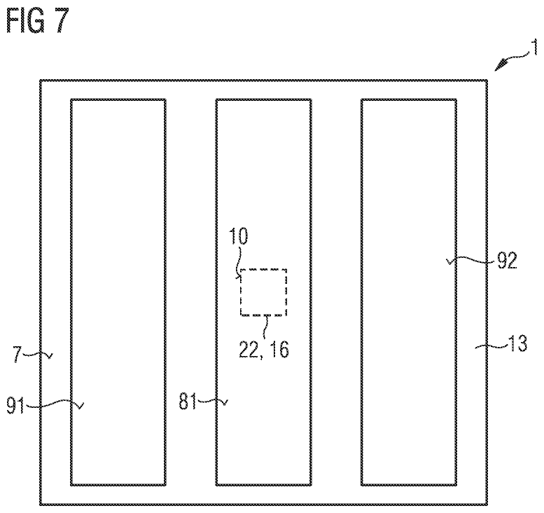

FIG. 7 illustrates an optoelectronic semiconductor chip 1 according to a further exemplary embodiment in view of the assembly side 7. In contrast to the semiconductor chip 1 of FIG. 4, the semiconductor chip 1 of FIG. 7 comprises a mesa structure 16 which forms a second emission region 22 in a central region of the semiconductor chip 1. In view of the assembly side 7, mesa edges 10 of the mesa structure 16 are spaced from edges of the semiconductor chip 1. In the present case, the first contact structure 8 and the second contact structure 9 are formed with a rewiring plane, for example, so that the second electrical connection surface 92 is assigned to the second emission region 22. With the rewiring plane, it is possible for the first electrical connection surface 81 to be arranged between the second electrical connection surfaces 91, 92.

Unless otherwise indicated, the components shown in the figures preferably follow one another directly in the sequence shown. Components not touching each other according to the figures are preferably spaced apart. Insofar as lines run parallel in the figures, associated surfaces are preferably also aligned parallel to one another.

The invention is not limited by the description based on the exemplary embodiments to these. Rather, the invention encompasses any new feature as well as any combination of features, which in particular includes any combination of features in the patent claims even if this feature or combination itself is not explicitly stated in the patent claims or the exemplary embodiments.

1-17. (canceled)

18. An optoelectronic semiconductor chip comprising:
an emission side;
an assembly side opposite the emission side; and
a semiconductor body comprising:
a first semiconductor layer;
a second semiconductor layer; and
an active zone between the first semiconductor layer and the second semiconductor layer,
wherein the semiconductor body has at least two emission regions which are arranged next to each other in view of the emission side,
wherein a first emission region of the at least two emission regions comprises a first portion of the active zone,
wherein a second emission region of the at least two emission regions comprises a second portion of the active zone,
wherein the two emission regions are monolithically integrated in the semiconductor body,
wherein, in a cross-section along a main extension plane of the active zone, the first portion of the active zone has an area which is at least twice as large as the second portion of the active zone,
wherein the emission regions are electrically separated from each other by a separation zone of the semiconductor body, and
wherein an electrical conductivity of the second semiconductor layer in the separation zone is lower by at least a factor of 10 than in a remaining second semiconductor layer.

19. The optoelectronic semiconductor chip according to claim 18,
wherein the first emission region has a first maximum luminous flux,
wherein the second emission region has a second maximum luminous flux, and
wherein the first maximum luminous flux and the second maximum luminous flux are different from each other.

20. The optoelectronic semiconductor chip according to claim 19, wherein the first maximum luminous flux is at least a factor of 2 greater than the second maximum luminous flux.

21. The optoelectronic semiconductor chip according to claim 18,
wherein the second emission region comprises a mesa structure,
wherein mesa edges of the mesa structure completely penetrate the second semiconductor layer and the active zone of the semiconductor body starting from the assembly side, and
wherein the second portion of the active zone is bounded by the mesa edges.

22. The optoelectronic semiconductor chip according to claim 21, wherein, in viewed of the assembly side, the mesa structure is formed in a central region of the semiconductor body.

23. The optoelectronic semiconductor chip according to claim 18,
wherein each of the first semiconductor layer, the second semiconductor layer and the active zone is formed as continuous layers, and
wherein the emission regions are electrically separated from one another by the separation zone.

24. The optoelectronic semiconductor chip according to claim 18, wherein the second semiconductor layer in the separation zone has a defect density which is at least a factor of 2 greater than a defect density outside the separation zone.

25. The optoelectronic semiconductor chip according to claim 18,
wherein the first semiconductor layer is arranged between the active zone and the emission side,
wherein the semiconductor body has at least one recess which extends from the assembly side into the first semiconductor layer,
wherein a first contact structure is arranged at least partially in the recess,
wherein the first semiconductor layer is electrically conductively connected to the first contact structure,
wherein the first contact structure has a first electrical connection surface, and
wherein the first electrical connection surface is arranged on the assembly side.

26. The optoelectronic semiconductor chip according to claim 25, wherein a side of the second semiconductor layer facing away from the emission side and side surfaces of the semiconductor body running transversely thereto are covered at least in places by a passivation layer, the passivation layer having breakthroughs in which the first contact structure and/or a second contact structure are/is arranged.

27. The optoelectronic semiconductor chip according to claim 18,
wherein the second semiconductor layer is electrically conductively connected to a second contact structure,
wherein the second contact structure comprises at least two second electrical connection surfaces,
wherein at least one of the second electrical connection surfaces is assigned to each emission region, and
wherein the second electrical connection surfaces of the second contact structure are arranged on the assembly side of the semiconductor chip.

28. The optoelectronic semiconductor chip according to claim 27, wherein all second electrical connection surfaces are of the same size in a projection onto the assembly side.

29. The optoelectronic semiconductor chip according to claim 18,
wherein the semiconductor chip has a single contiguous emission surface, and wherein all emission regions are configured to emit radiation through the emission surface.

30. The optoelectronic semiconductor chip according to claim 18, wherein all emission regions are configured to emit radiation of the same wavelength range.

31. The optoelectronic semiconductor chip according to claim 18, wherein the semiconductor chip is a micro-LED.

32. The optoelectronic semiconductor chip according to claim 18,
wherein the second emission region comprises a mesa structure,
wherein mesa edges of the mesa structure completely penetrate the second semiconductor layer and the active zone of the semiconductor body, starting from the assembly side,
wherein the mesa edges terminate in the first semiconductor layer, and
wherein the second portion of the active zone is bounded by the mesa edges.

33. A method for operating the optoelectronic semiconductor chip according to claim 18, the method comprising:
predetermining a target luminous flux for the semiconductor chip;
determining the emission regions required to generate the predetermined target luminous flux; and
supplying the first emission region or the second emission region or the first and second emission regions with current so that the semiconductor chip as a whole emits the predetermined target luminous flux.

34. The method according to claim 33, wherein the first emission region is supplied with an operating current that is different from an operating current of the second emission region.
